(19) United States
(12) Patent Application Publication
(10) Pub. No.: US 2026/0068633 A1
(43) Pub. Date: Mar. 5, 2026

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: CHING-YEN LIN, HSINCHU (TW); CHUNG-TING LU, KAOHSIUNG CITY (TW); SHU-CHIN TAI, HSINCHU CITY (TW); YUNG-CHOW PENG, HSINCHU (TW); TZUNG-YO HUNG, HSINCHU (TW)

(21) Appl. No.: 18/822,432

(22) Filed: Sep. 2, 2024

(51) Int. Cl. H01L 23/528; H01L 21/8238; H01L 23/522; H01L 27/092

(52) U.S. Cl. CPC H01L 23/5286; H10D 84/0186; H10D 84/038; H10D 84/85

(57) ABSTRACT

A semiconductor device and method of manufacturing the same are provided. The semiconductor device includes a first gate, a first contact, a first backside interconnection, and a conductive layer. The first gate extends along a first direction and is configured to receive a first voltage. The first contact extends along the first direction and is configured to receive a second voltage different from the first voltage. The first backside interconnection is electrically coupled to the first contact. The conductive layer is over and electrically coupled to the first gate and extends along a second direction different from the first direction. The first gate and the first contact collectively form a first capacitor.

### BACKGROUND

Currently, semiconductor devices are widely used in various fields, such as cloud storage, medicine, transportation, mobile devices, etc. The current trend in some aspects of semiconductor device manufacturing focuses on providing semiconductor devices with smaller dimensions and better power efficiency. It is therefore desirable to continuously improve the structure and manufacturing of the semiconductor devices.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1A illustrates a top view of a layout of a semiconductor device, in accordance with some embodiments of the present disclosure.

FIG. 1B illustrates a partial layout of the semiconductor device as shown in FIG. 1A, in accordance with some embodiments of the present disclosure.

FIG. 1C illustrates a partial layout of the semiconductor device as shown in FIG. 1A, in accordance with some embodiments of the present disclosure.

FIG. 2A illustrates a cross-sectional view along line A-A′ of the semiconductor device as shown in FIG. 1A, in accordance with some embodiments of the present disclosure.

FIG. 2B illustrates a cross-sectional view along line B-B′ of the semiconductor device as shown in FIG. 1A, in accordance with some embodiments of the present disclosure.

FIG. 2C illustrates a cross-sectional view along line C-C′ of the semiconductor device as shown in FIG. 1A, in accordance with some embodiments of the present disclosure.

FIG. 2D illustrates a cross-sectional view along line D-D′ of the semiconductor device as shown in FIG. 1A, in accordance with some embodiments of the present disclosure.

FIG. 3 illustrates a top view of a layout of a semiconductor device, in accordance with some embodiments of the present disclosure.

FIG. 4A illustrates a cross-sectional view along line A-A′ of the semiconductor device as shown in FIG. 3, in accordance with some embodiments of the present disclosure.

FIG. 4B illustrates a cross-sectional view along line B-B′ of the semiconductor device as shown in FIG. 3, in accordance with some embodiments of the present disclosure.

FIG. 4C illustrates a cross-sectional view along line C-C′ of the semiconductor device as shown in FIG. 3, in accordance with some embodiments of the present disclosure.

FIG. 4D illustrates a cross-sectional view along line D-D′ of the semiconductor device as shown in FIG. 3, in accordance with some embodiments of the present disclosure.

FIG. 5 illustrates a top view of a layout of a semiconductor device, in accordance with some embodiments of the present disclosure.

FIG. 6A illustrates a top view of a layout of a semiconductor device, in accordance with some embodiments of the present disclosure.

FIG. 6B illustrates a partial layout of the semiconductor device as shown in FIG. 6A, in accordance with some embodiments of the present disclosure.

FIG. 6C illustrates a partial layout of the semiconductor device as shown in FIG. 6A, in accordance with some embodiments of the present disclosure.

FIG. 6D illustrates a partial layout of the semiconductor device as shown in FIG. 6A, in accordance with some embodiments of the present disclosure.

FIG. 7 is a flow chart illustrating a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure integrates the super power rail (SPR) technique and decoupling capacitors. In some embodiments, backside interconnections (e.g., VB) and/or backside conductive layers (e.g., BM0, BM1, BM2, and similar) are used to build a conductive path of capacitors. As a result, the capacitance density of a semiconductor device can be improved.

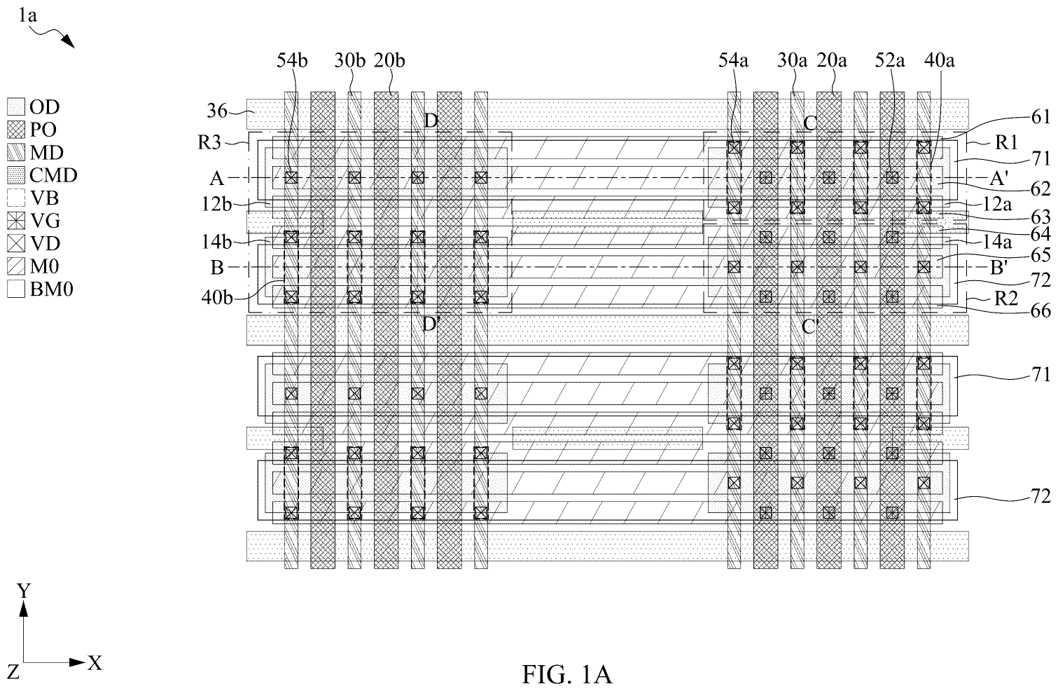

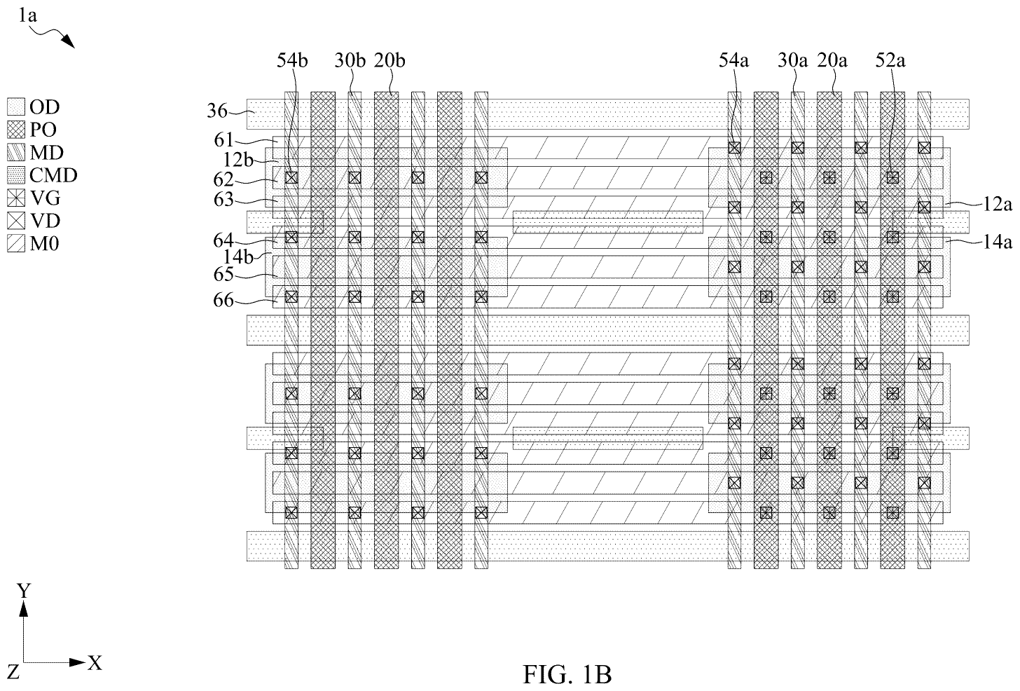

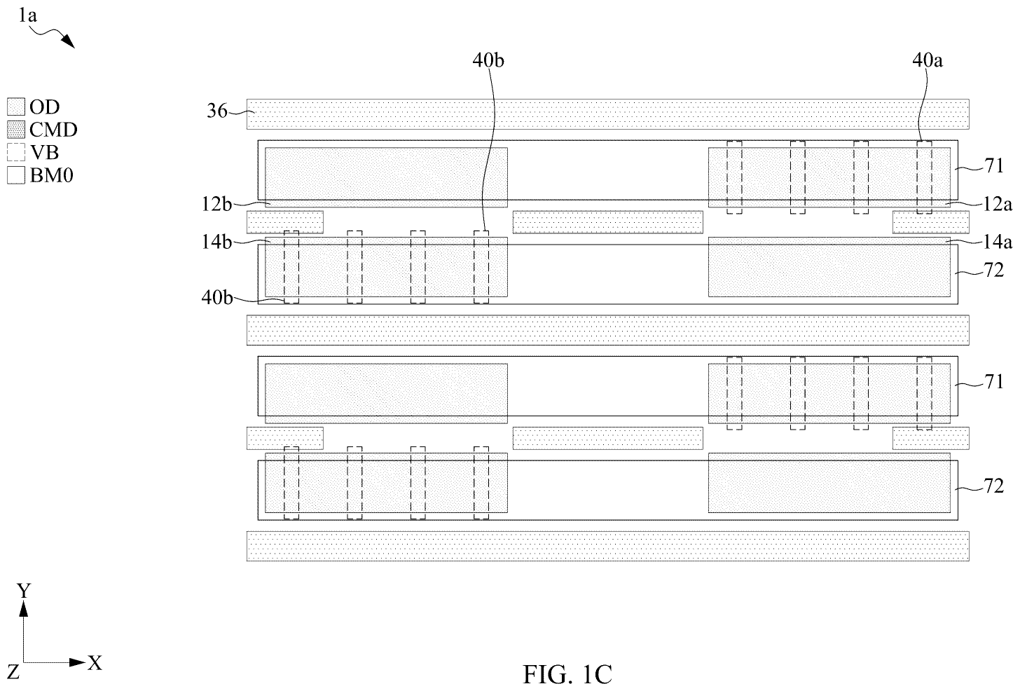

FIG. 1A illustrates a layout of a semiconductor device 1a, in accordance with some embodiments of the present disclosure, and FIGS. 1B and 1C illustrate partial layouts of FIG. 1A for brevity. More specifically, FIG. 1B illustrates features disposed on or abutting a front side of the semiconductor device 1a, and FIG. 1C illustrates features disposed on or abutting a backside side of the semiconductor device 1a.

In some embodiments, the semiconductor device 1a includes regions R1, R2 and R3. In some embodiments, the region R1 and/or R2 is configured to define or accommodate a transistor, such as a metal-oxide-semiconductor field-effect transistor (MOSFET). In some embodiments, the region R1 and/or R2 is configured to define or accommodate a p-type transistor (e.g., PMOS) or n-type transistor (e.g., NMOS). In some embodiments, the regions R1, R2, or a combination thereof include an NMOS(s). In some embodiments, the regions R1, R2, or a combination thereof include a PMOS(s). The transistor may include a field-effect transistor (FinFET), nano-sheet transistor, and nano-wire transistor, or other suitable transistors. In some embodiments, the region R3 is configured to define or accommodate a protective structure for protecting the device (e.g., transistors within the regions R1 and R2). For example, the region R3 may be configured to define or accommodate a guard ring structure. In some embodiments, an isolation region (e.g., a shallow trench isolation (STI) region) or a dummy region (not denoted) is disposed between the regions R1 and R3 and between the regions R2 and R3.

In some embodiments, the semiconductor device 1a includes active region structures 12a, 12b, 14a, and 14d, gate structures 20a and 20b, source/drain (S/D) contacts 30a and 30b, backside interconnections 40a and 40b.

Each of the active region structures 12a, 12b, 14a and 14b extends along the X direction. The active region structure 12a is disposed within the region R1. The active region structure 14a is disposed within the region R2. The active region structures 12b and 14b are disposed within the region R3. The active region structures 12a and 12b are located at the same row and overlap along the X direction. The active region structures 14a and 14b are located at the same row and overlap along the X direction. The active region structure 12a overlaps the active region structure 14a along the Y direction. The active region structure 12b overlaps the active region structure 14b along the Y direction. Non-limiting examples of the active region structures 12a, 12b, 14a and 14b are configured to define or parts of a fin field-effect transistor (FinFET), nano-sheet transistor, and nano-wire transistor. In some embodiments, the active region structures 12a, 12b, 14a and 14b are separated by an isolation structure, such as STI. In some embodiments, the active region structures 12a, 12b, 14a and 14b can be referred to as an oxide definition region (also referred to as “OD”).

Referring to FIGS. 1A and 1B, the gate structures 20a are disposed within the regions R1 and R2. The gate structures 20b are disposed within the region R3. Each of the gate structures 20a and 20b extends along the Y direction. The gate structures 20a and 20b are disposed on a front-side of a substrate (e.g., silicon substrate). In some embodiments, each of the gate structures 20a and 20b includes a gate dielectric and a gate electrode. The gate dielectric may include or be made of a high-k dielectric material, such as a metal oxide or silicate of hafnium, aluminum, zirconium, lanthanum, manganese, barium, titanium, lead, other suitable materials, or any combination thereof, and may be made by CVD, atomic layer deposition (ALD), other suitable techniques, or any combination thereof. The gate electrode may include or be made of titanium nitride, titanium oxide, tantalum nitride, tantalum carbide, cobalt, ruthenium, aluminum, tungsten, other suitable materials, or any combination thereof, and may be made by physical vapor deposition (PVD), other suitable techniques, or any combination thereof. In some embodiments, the gate structures 20a and 20b include nanostructures, nanowires, or nano-sheets, which may include or be made of silicon, silicon germanium, silicon carbide, other suitable materials, or any combination thereof, and may be made by CVD, ALD, other suitable techniques, or any combination thereof. In some embodiments, the gate structures 20a and 20b can be referred to as poly (PO) of a semiconductor device.

The S/D contacts 30a are disposed within the regions R1 and R2. The S/D contacts 30b are disposed within the region R3. Each of the S/D contacts 30a and 30b extends along the Y direction. The S/D contacts 30a and 30b are disposed on a front-side of a substrate (e.g., silicon substrate). In some embodiments, each of the S/D contacts 30a and 30b includes a source/drain (S/D) contact, which is electrically coupled to and disposed on an S/D feature. The S/D contacts 30a and 30b may include or be made of Cu, Ni, Ti, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof. In some embodiments, the S/D contacts 30a and 30b can be referred to as metal diffusion conductive feature (MD).

In some embodiments, the semiconductor device 1a further includes cut-MD layers 36. The cut-MD layers 36 extend along the X direction and have different lengths along the X direction and/or Y direction. The cut-MD layer 36 overlaps the S/D contact 30a and/or 30b along the Z direction. In some embodiments, the cut-MD layer 36 is configured to disconnect the S/D contact 30a and/or 30b to avoid leakage between the MDs. In some embodiments, the cut-MD layer 36 may include or be made of silicon oxide, silicon nitride, silicon oxynitride, other suitable materials, or any combination thereof, and may be made by CVD, PVD, other suitable techniques, or any combination thereof. In some embodiments, the cut-MD layer 36 can be referred to as an MD cut layer “CMD” or a source/drain contact cut layer.

In some embodiments, the semiconductor device 1a further includes frontside interconnections 52a. The frontside interconnections 52a are disposed within the regions R1 and R2. In some embodiments, the frontside interconnection 52a overlaps the gate structure 20a along the Z direction. The frontside interconnection 52a is disposed on or over the gate structure 20a. The frontside interconnection 52a is electrically coupled to the gate structure 20a. In some embodiments, the frontside interconnection 52a can be referred to as “VG.”

In some embodiments, the semiconductor device 1a further includes frontside interconnections 54a and 54b. The frontside interconnections 54a are disposed within the regions R1 and R2. The frontside interconnections 54b are disposed within the region R3. In some embodiments, the frontside interconnection 54a overlaps the S/D contact 30a along the Z direction. The frontside interconnection 54a is disposed on or over the S/D contact 30a. The frontside interconnection 54a is electrically coupled to the S/D contact 30a. In some embodiments, the frontside interconnection 54b overlaps the S/D contact 30b along the Z direction. The frontside interconnection 54b is disposed on or over the S/D contact 30b. The frontside interconnection 54b is electrically coupled to the S/D contact 30b. Each of the frontside interconnections 52a, 54a, and 54b may include or be made of Cu, Ni, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof.

In some embodiments, the semiconductor device 1a further includes frontside conducive layers 61, 62, 63, 64, 65, and 66. Each of the frontside conductive layers 61 to 66 extends along the X direction. Each of the frontside conductive layers 61 to 66 is disposed over the gate structures 20a and 20b and over the S/D contacts 30a and 30b. The frontside conductive layers 61, 62, 63, 64, 65, and/or 66 may be electrically coupled to gate structure 20a through the frontside interconnections 52a. The frontside conductive layers 61, 62, 63, 64, 65, and/or 66 may be electrically coupled to the S/D contact 30a through the frontside interconnections 54a or electrically coupled to the S/D contact 30b through the frontside interconnections 54b. In some embodiments, each of the frontside conductive layers 61, 63, and 65 is electrically coupled to the S/D contacts 30a through the frontside interconnections 54a of the region R1 (or R2). In some embodiments, no frontside interconnections are disposed between the conductive layer 61 (or conductive layer 63 or 65) and the S/D contact 30b. In some embodiments, no frontside interconnections are disposed between the conductive layer 61 (or conductive layer 63 or 65) and the gate structure 20b. In some embodiments, each of the frontside conductive layers 62, 64, and 66 is electrically coupled to the gate structures 20a through the frontside interconnections 52a of the region R1 (or R2). In some embodiments, each of the frontside conductive layers 62, 64, and 66 is electrically coupled to the S/D contacts 30b through the frontside interconnections 54b of the region R3. The frontside conductive layers 61 to 66 may include or be made of Cu, Ni, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof. Each of the frontside conductive layers 61 to 66 can be referred to as a metal zero (M0) layer.

Referring to FIGS. 1A and 1C, each of the backside interconnections 40a and 40b extends along the Y direction. The backside interconnections 40a and 40b are disposed on a backside of a substrate (e.g., silicon substrate). The backside interconnections 40a are disposed within the region R1. The backside interconnection 40a overlaps the active region structure 12a along the Z direction. The backside interconnections 40b are disposed within the region R3. The backside interconnection 40b overlaps the active region structure 14b along the Z direction. In some embodiments, the backside interconnections 40a and 40b are free overlapping along the X direction. For example, the backside interconnections 40a and 40b are arranged alternatively, wherein the backside interconnections 40a are arranged at the first row, and the backside interconnections 40b are arranged at the second row. In some embodiments, the active region structure 12b is free from overlapping a backside interconnection along the Z direction. In some embodiments, the active region structure 14a is free from overlapping a backside interconnection along the Z direction. The backside interconnections 40a and 40b may include or be made of Cu, Ni, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof. In some embodiments, a portion of a substrate (e.g., silicon substrate) under S/D features can be etched to form trenches, and a conductive material can be filled within the trenches to form backside interconnections. However, the scope of the disclosure is not intended to be limiting. In some embodiments, the backside interconnections 40a and 40b can be referred to as a backside via (VB).

In some embodiments, the semiconductor device 1a further includes backside conductive layers 71 and 72. Each of the backside conductive layers 71 and 72 extends along the X direction. The backside conductive layer 71 overlaps the active region structures 12a and 12b along the Z direction. In some embodiments, the backside conductive layer 71 is electrically connected to the backside interconnections 40a and overlaps the backside interconnections 40a along the Z direction. The backside conductive layer 72 overlaps the active region structures 14a and 14b along the Z direction. In some embodiments, the backside conductive layer 72 is electrically connected to the backside interconnections 40b and overlaps the backside interconnections 40b along the Z direction. The backside conductive layers 71 and 72 may include or be made of Cu, Ni, Co, Ru, Ir, Al, Pt, Pd, Au, Ag, Os, Mo, W, other suitable materials, or any combination thereof, and may be made by CVD, ALD, PVD, plating (including electroplating, electroless plating, etc.), other suitable techniques, or any combination thereof. In some embodiments, the backside conductive layers 71 and 72 can be referred to as a backside metal zero (BM0) layer.

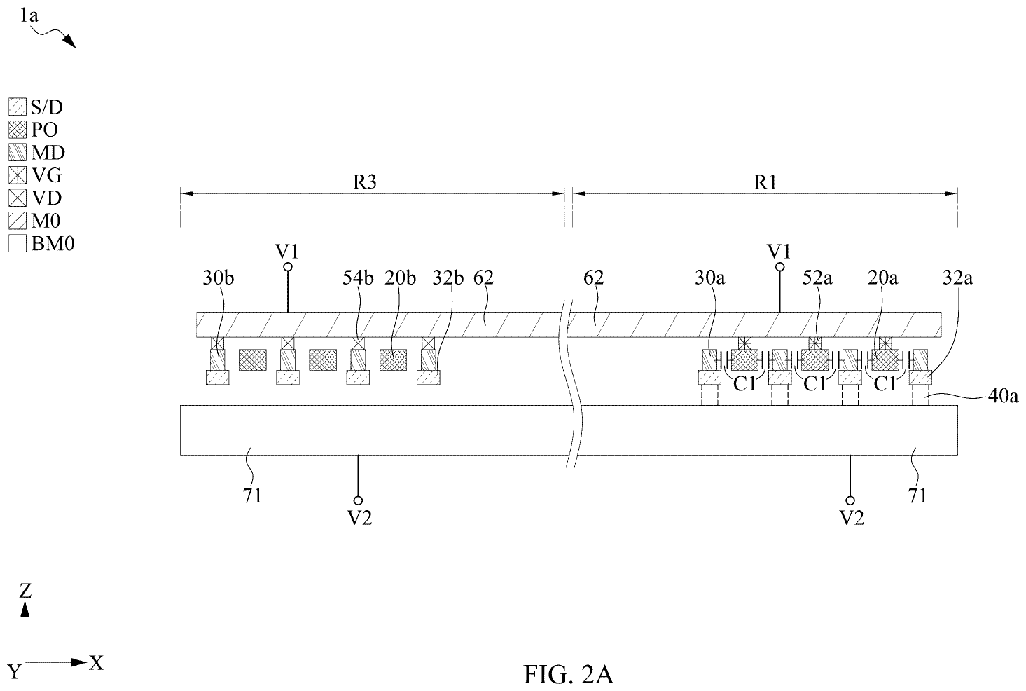

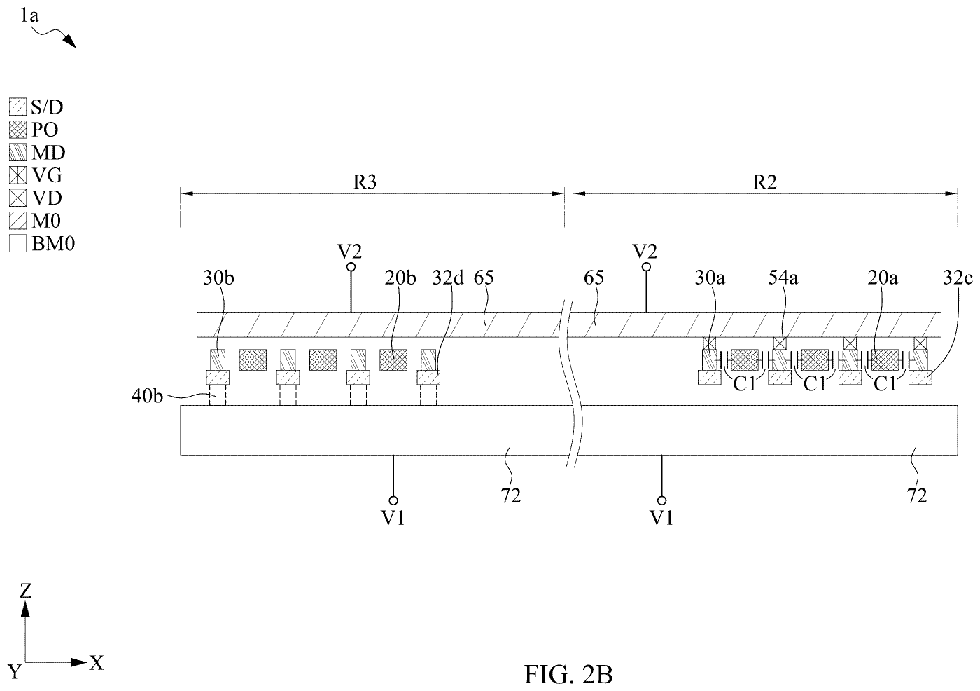

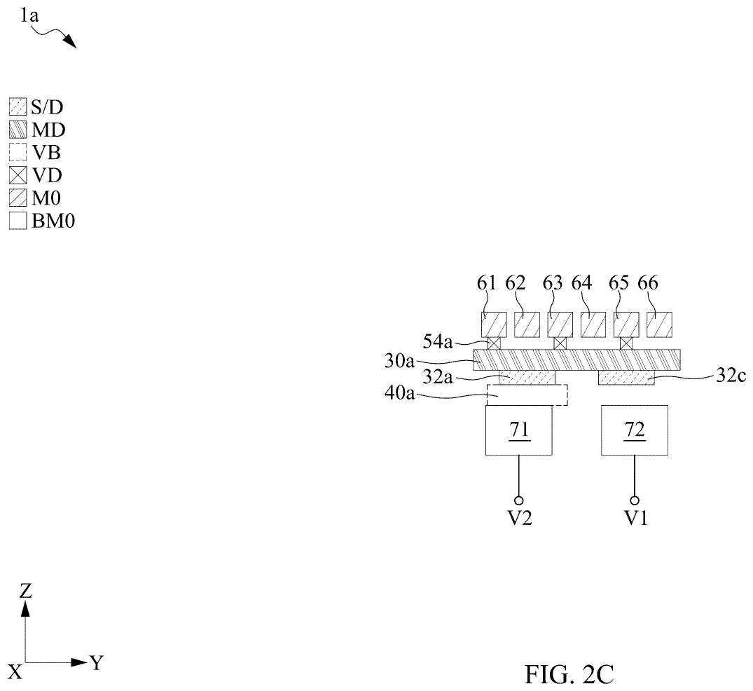

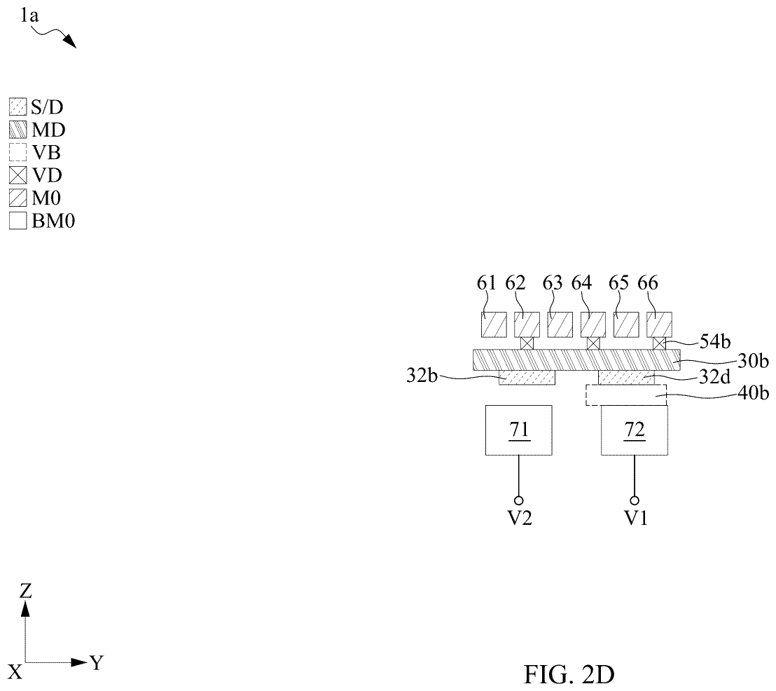

FIGS. 2A, 2B, 2C, and 2D are cross-sectional views of FIG. 1A along lines A-A′, B-B′, C-C′ and D-D′, respectively. In some embodiments, the semiconductor device 1a further includes S/D features 32a, 32b, 32c, and 32d. The S/D features 32a are disposed on the opposite sides of the gate structures 20a and within the region R1. The S/D features 32c are disposed on the opposite sides of the gate structures 20a and within the region R2. The S/D features 32b and 32d are disposed on the opposite sides of the gate structures 20b and within the region R3. The S/D features 32a to 32d are disposed under the S/D contacts 30a and 30b. In some embodiments, the S/D features 32a are electrically coupled to the backside conductive layer 71 through the backside interconnections 40a. In some embodiments, the S/D features 32d are electrically coupled to the backside conductive layer 72 through the backside interconnections 40b. In some embodiments, each of the S/D features 32a to 32d includes an epitaxial structure. The materials of the epitaxial structure may be varied for the n-type and p-type transistor. For example, SiP, SiCP or SiC may be used to form n-type transistors, and SiGe or Ge may be used to form p-type transistors. In some embodiments, boron (B) is doped in the epitaxial structure for the p-type transistors. Other materials can be used. In some embodiments, the epitaxial structure includes two or more epitaxial layers with different compositions and/or different dopant concentrations. The epitaxial structure may be made by CVD, ALD, vapor phase epitaxy (VPE), molecular beam epitaxy (MBE), other suitable techniques, or any combination thereof. The S/D features 32a to 32d can also be referred to as “S/D.”

As shown in FIG. 2D, a voltage V1 (or power) is imposed on or applied to the backside conductive layer 72. The voltage V1 can be transmitted from the backside conductive layer 72 to the frontside conductive layers 62, 64, and 66 through the frontside interconnections 54b, the S/D contacts 30b, the S/D features 32d, and the backside interconnections 40b. As shown in FIGS. 2A and 2D, the voltage V1 is imposed on or applied to the gate structures 20a through the frontside conductive layers 62, 64, and 66 as well as the frontside interconnection 52a. In some embodiments, the voltage V1 is imposed on or applied to the S/D contacts 30b through the frontside conductive layers 62, 64, and 66 as well as the frontside interconnections 54b.

As shown in FIG. 2C, a voltage V2 (or power), different from the voltage V1, is imposed on or applied to the backside conductive layer 71. The voltage V2 can be transmitted from the backside conductive layer 71 to the frontside conductive layers 61, 63, and 65 through the frontside interconnections 54a, the S/D contacts 30a, the S/D features 32a, and the backside interconnections 40a. As shown in FIGS. 2B and 2C, the voltage V2 is imposed on or applied to the S/D contacts 30a through the front interconnections 54a and the frontside conductive layers 61, 63, and 65.

In some embodiments, the gate structures 20b in the region R3 are electrically floating. For example, the gate structure 20b is free of being electrically coupled to a frontside interconnection (e.g., VG); the gate structure 20b is free of being electrically coupled to a backside interconnection (e.g., VB).

Although not shown in FIGS. 2A to 2D, the semiconductor device 1a includes a substrate, such as a bulk semiconductor, a semiconductor-on-insulator (SOI) substrate, or the like, which may be doped (e.g., with a p-type or an n-type dopant) or undoped. The substrate may be a wafer, such as a silicon wafer. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlinAs, AlGaAs, GalnAs, GaInP, and/or GaInAsP; or combinations thereof. The substrate may be etched to form a plurality of fins, and an isolation structure, such as STI, may be formed and surrounded by the fins. During the SPR processes, portions of the substrate are removed to form the backside interconnections and dielectric layers that encapsulate the backside interconnections. In some embodiments, the fins can remain and be disposed under the gate structures. However, the scope of the disclosure is not intended to be limiting.

In some embodiments, the S/D contacts 30a and the gate structures 20a exhibit or define a capacitance C1 in the regions R1 and R2. Since the gate structures 20b are electrically floating, the S/D contacts 30b and the gate structures 20b do not exhibit or define a capacitance C1 in the region R3.

In some embodiments, the SPR technique or backside power rails are introduced to alleviate routing pressure from the frontside interconnect structure. This includes the configuration of backside interconnections (e.g., VB) and backside conductive layers (e.g., BM0, BM1, BM2, and similar) to transmit a power signal. In some embodiments, the SPR technique is also configured to build a conductive path of capacitances, such as decoupling capacitors. Additionally, the guard ring region is configured to build a conductive path of capacitances, with the backside interconnections (e.g., backside interconnection 40a and/or 40b) and backside conductive layers within the guard ring region (region R3) being coupled to the gate structure 20a within a transistor region (region R1 and/or R2), such as PMOS region or NMOS region. As a result, the capacitance density of the semiconductor device 1a can be improved without requiring extra area.

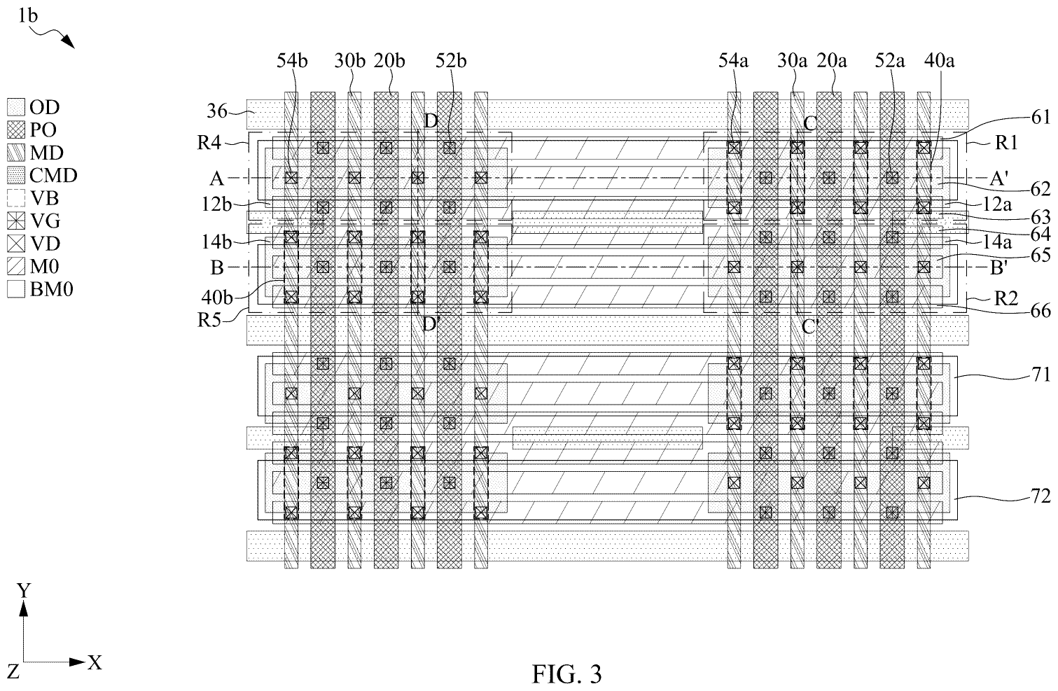

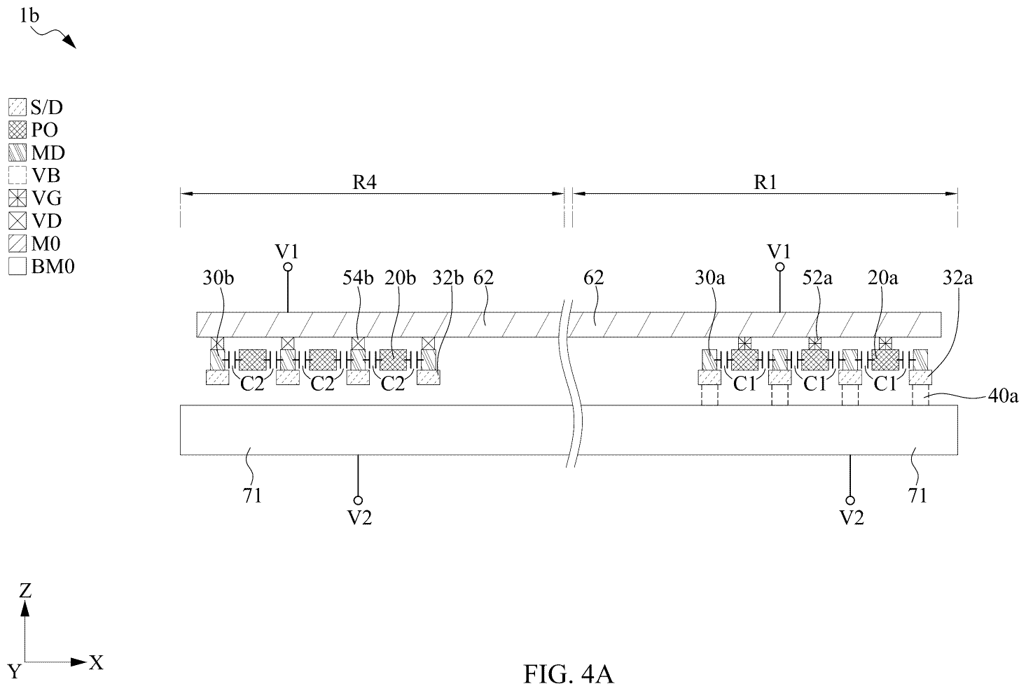

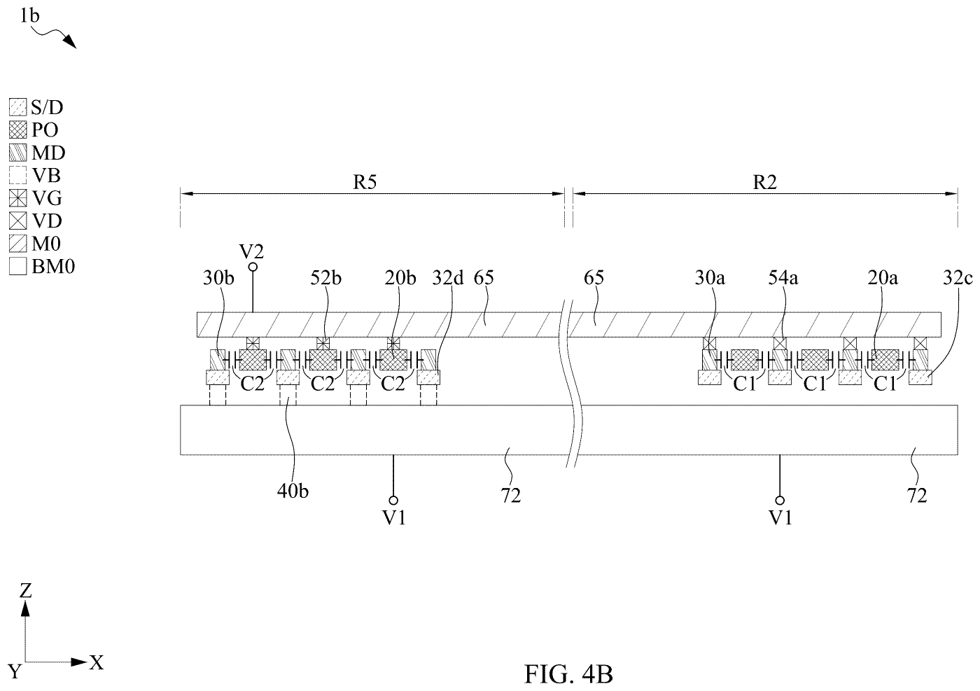

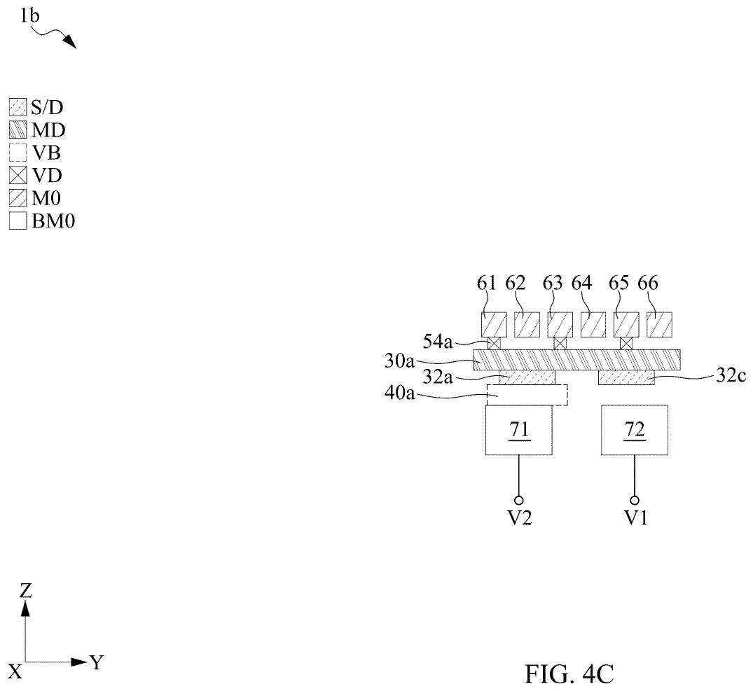

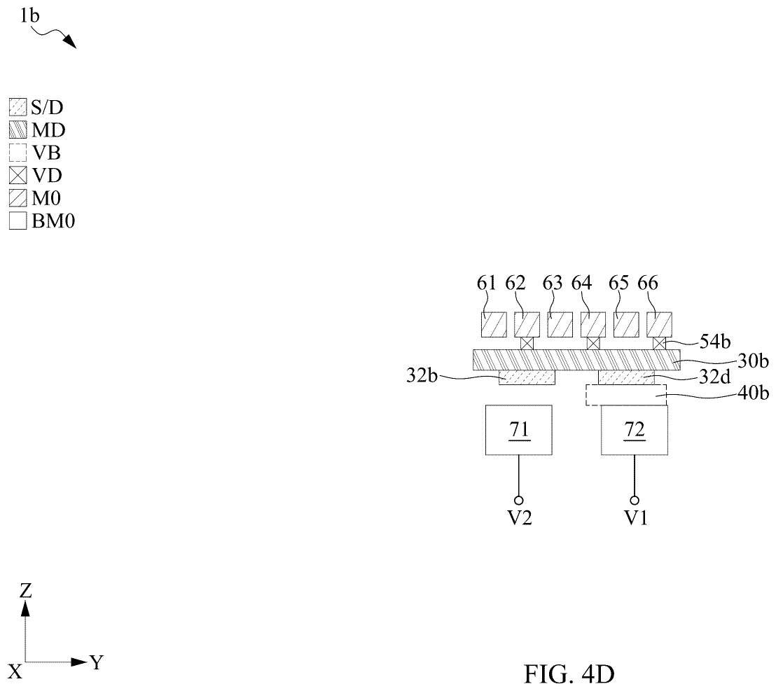

FIGS. 3, 4A and 4B illustrate a semiconductor device 1b, in accordance with some embodiments of the present disclosure. The semiconductor device 1b has a structure similar to that of the semiconductor device 1a. One of the differences between the semiconductor devices 1b and 1a is that the semiconductor devices 1b includes regions R4 and R5.

As shown in FIG. 3, the region R4 is aligned with the region R1 along the X direction. The region R5 is aligned with the region R2 along the X direction. In some embodiments, the regions R1 and R2 are configured to define or accommodate a first type transistor, and the regions R4 and R5 are configured to define or accommodate a second type transistor. In some embodiments, the regions R1 and R2 include an NMOS(s), and the regions R4 and R5 include a PMOS(s). In some embodiments, the gate structures 20b, the S/D contacts 30b, and the frontside interconnections 54b are disposed within the regions R4 and R5. In some embodiments, the backside interconnections 40b are disposed within the region R5. In some embodiments, an isolation region (not denoted) or a dummy region is disposed between the regions R1 and R4 and between the regions R2 and R5.

In some embodiments, the semiconductor device 1b further includes frontside interconnections 52b. The frontside interconnections 52b are disposed within the regions R4 and R5. In some embodiments, the frontside interconnection 52b overlaps the gate structure 20b along the Z direction. The frontside interconnection 52b is disposed on or over the gate structure 20b. The frontside interconnection 52b is electrically coupled to the gate structure 20b. In some embodiments, the frontside interconnection 52b overlaps the frontside interconnection 54a along the X direction. In some embodiments, the frontside interconnection 52b overlap the frontside conductive layers 61, 63, and 65 along the Z direction. In some embodiments, the frontside interconnection 52b can be referred to as “VG.”

As shown in FIGS. 3, 4A, and 4D, the voltage V1 is applied to the S/D contacts 30b from the backside conductive layer 72 through the backside interconnections 40b and the S/D features 32d. The voltage V1 is applied to the gate structures 20a through the frontside conductive layers 62, 64, and 66 as well as the frontside interconnections 52a. As shown in FIGS. 3, 4B, and 4C, the voltage V2 is applied to the S/D contacts 30a from the backside conductive layer 71 through the backside interconnections 40a and the S/D features 32a. The voltage V2 is applied to the gate structures 20a through the frontside conductive layers 61, 63, and 65 as well as the frontside interconnections 52b.

As a result, the S/D contacts 30b and the gate structures 20b exhibit or define a capacitance C2 in the regions R4 and R5 as shown in FIGS. 4A and 4B. Since the capacitance C2 is built in the regions R4 and R5, the capacitance density of the semiconductor device 1b can be improved.

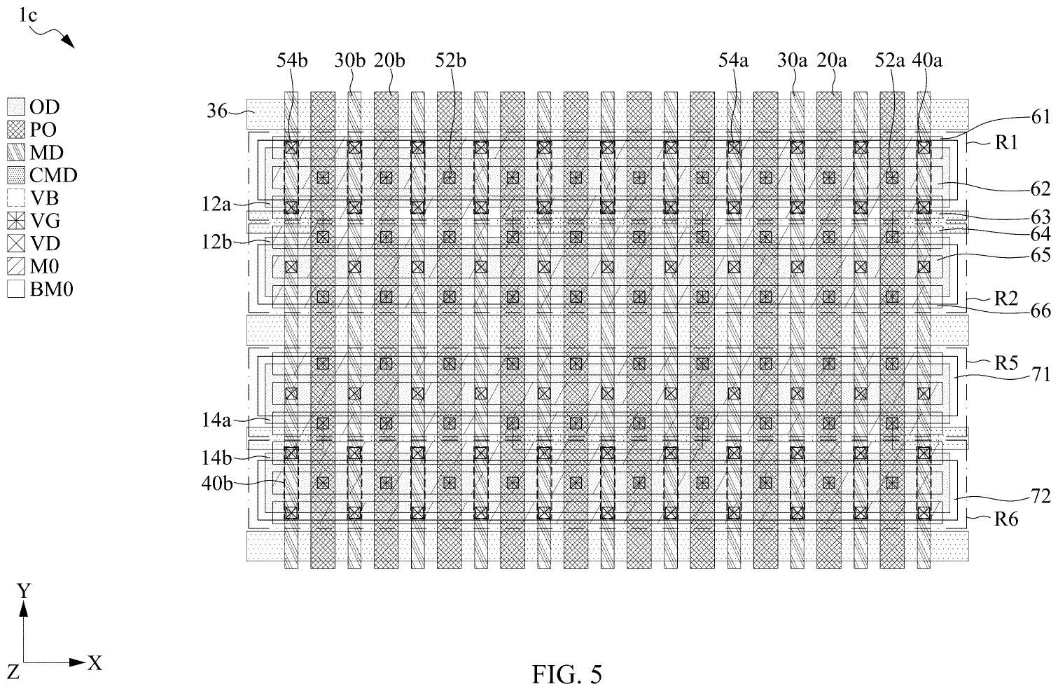

FIG. 5 illustrate a semiconductor device 1c, in accordance with some embodiments of the present disclosure. The semiconductor device 1c has a structure similar to that of the semiconductor device 1b. One of the differences between the semiconductor devices 1c and 1b is that the regions R5 and R6 of the semiconductor device 1c are aligned with the regions R1 and R2 along the Y direction.

The active region structures 12a, 12b, 14a and 14b may be arranged along the Y direction. In this embodiment, an isolation region or a dummy region laterally between the regions R1 and R4 as shown in FIG. 3 can be configured to form the gate structures, S/D contacts, and other features.

In some embodiments, the backside conductive layer 71 of the region R1 and the backside conductive layer 71 of the region R5 are electrically coupled. In some embodiments, the backside conductive layer 72 of the region R2 and the backside conductive layer 72 of the region R6 are electrically coupled. As a result, the capacitance between the gate structures 20a and S/D contacts 30a as well as between the gate structures 20b and S/D contacts 30b can be built in regions R1, R2, R5, and R6. Since more areas are configured to exhibit or define capacitances, the capacitance density of the semiconductor device 1c is improved.

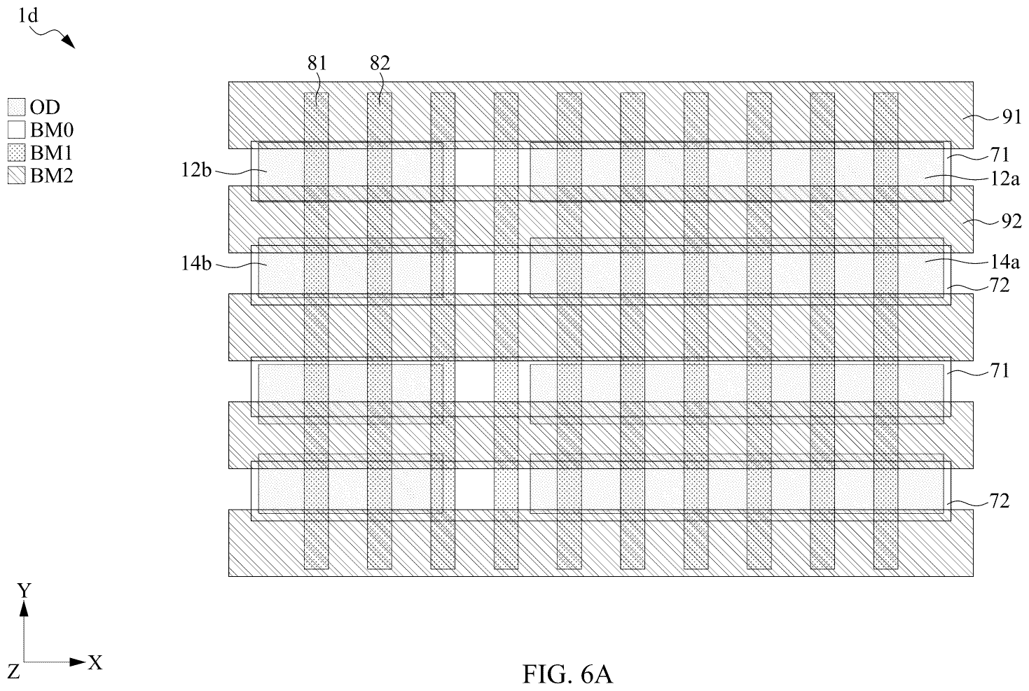

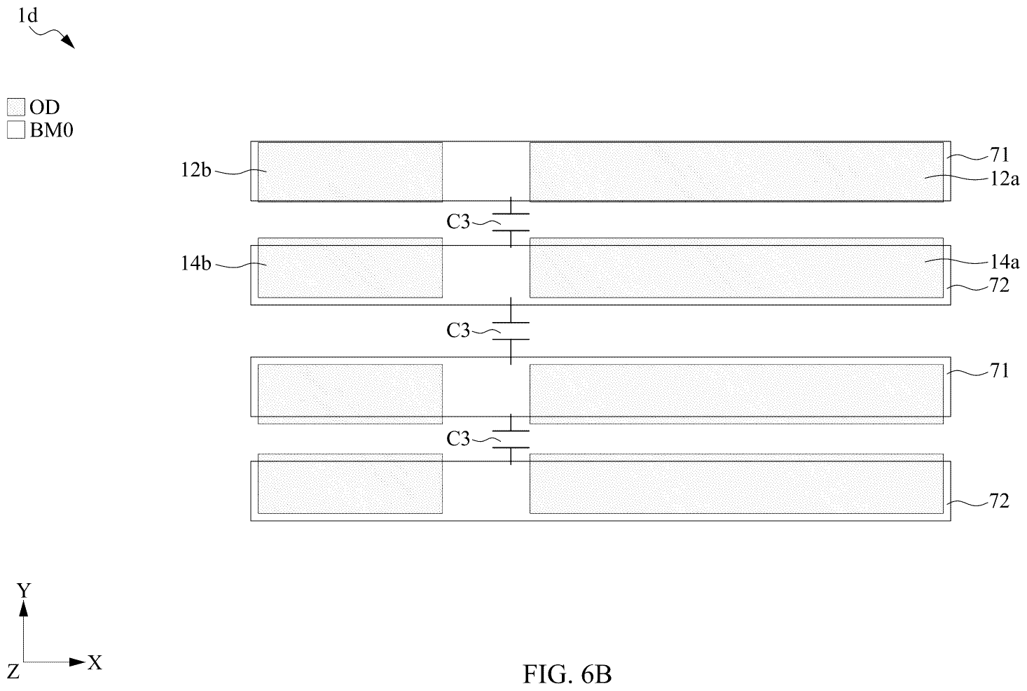

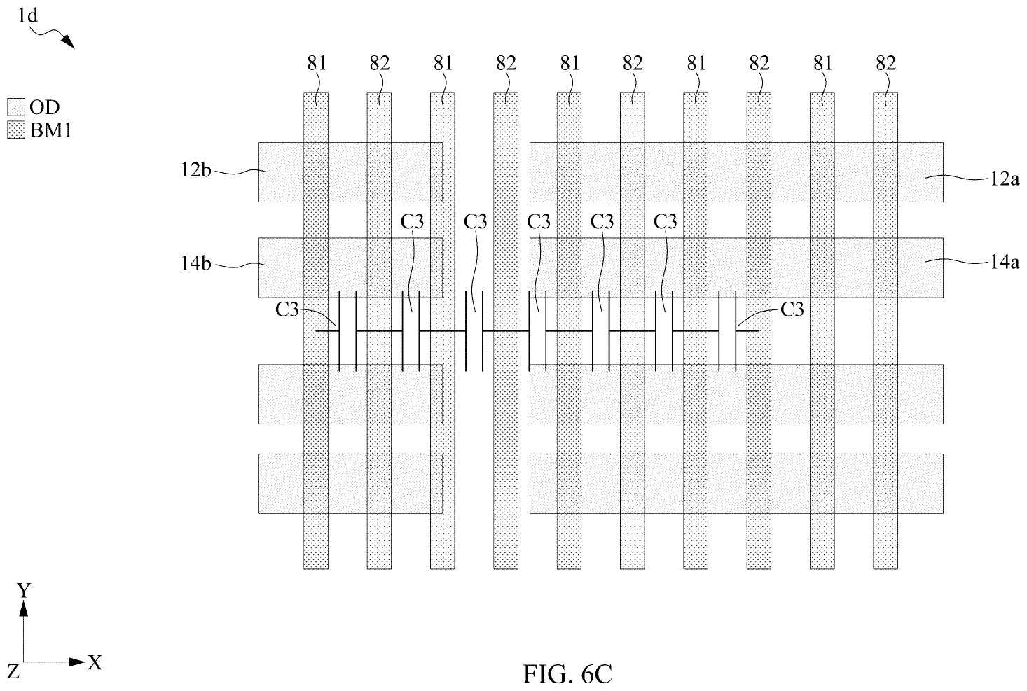

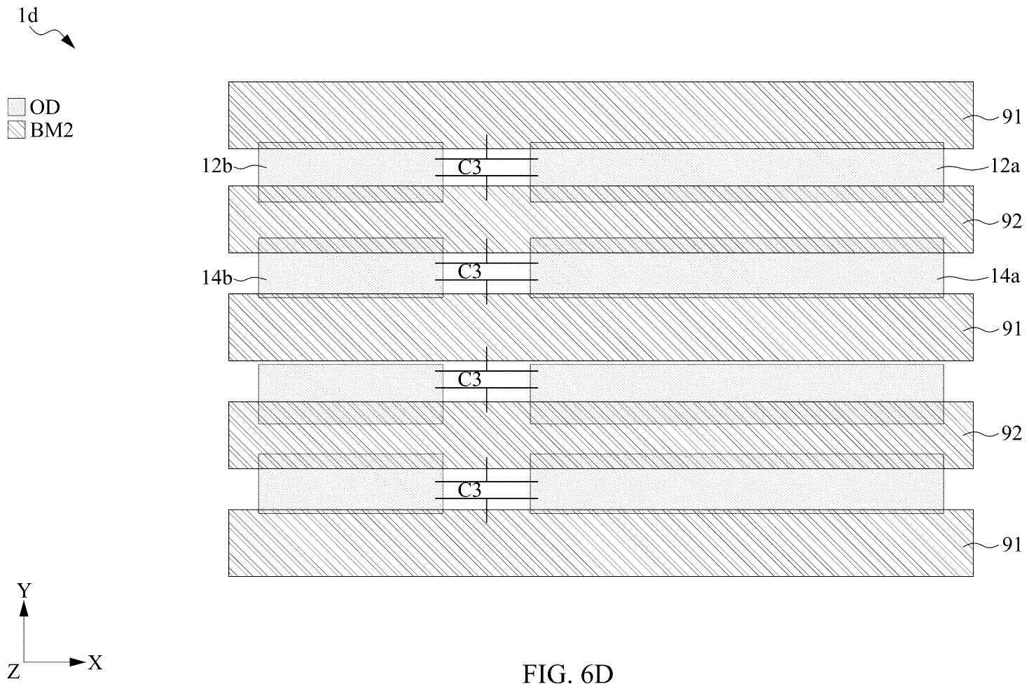

FIG. 6A illustrates a top view of a layout of a semiconductor device 1d, and FIGS. 6B, 6C, and 6D are partial layouts of FIG. 6A in accordance with some embodiments of the present disclosure. It should be noted that some features are omitted from FIG. 6A for brevity. For example, the features disposed on the frontside are omitted from FIG. 6. The features disposed on the frontside as shown in semiconductor devices 1a, 1b, and 1c can be applied to or integrated with the layout of the semiconductor device 1d.

In some embodiments, the backside of a substrate can be configured to exhibit or define a capacitance. In some embodiments, the semiconductor device 1d includes backside conductive layers 81 and 82. Each of the backside conductive layers 81 and 82 extends along the Y direction. The backside conductive layers 81 and 82 are disposed on or under the backside conductive layers 71 and 72. In some embodiments, the backside conductive layers 81 and 82 can be referred to as a backside metal one (BM1) layer.

In some embodiments, the semiconductor device 1d includes backside conductive layers 91 and 92. Each of the backside conductive layers 91 and 92 extends along the X direction. The backside conductive layers 91 and 92 are disposed on or under the backside conductive layers 81 and 82. In some embodiments, the backside conductive layers 91 and 92 can be referred to as a backside metal one (BM2) layer.

In some embodiments, the backside conductive layers 71, 81, and 91 are electrically coupled to a first voltage, and the backside conductive layers 72, 82, and 92 are electrically coupled to a second voltage different from the first voltage. It should be noted that the backside vias (or backside interconnections) between the backside conductive layers 71 and 81, between the backside conductive layers 72 and 82, between the backside conductive layers 81 and 91, and between the backside conductive layers 82 and 92 are omitted for brevity. As a result, the backside conductive layers 71, 72, 81, 82, 91, and 92 exhibit or define a capacitance C3. Further, the backside conductive layers 71, 72, 81, and 82 can exhibit or define a capacitance between BM0 and BM1, and the backside conductive layers 81, 82, 91, and 92 can exhibit or define a capacitance between BM1 and BM2. Therefore, the capacitance density of the semiconductor device 1d can be improved.

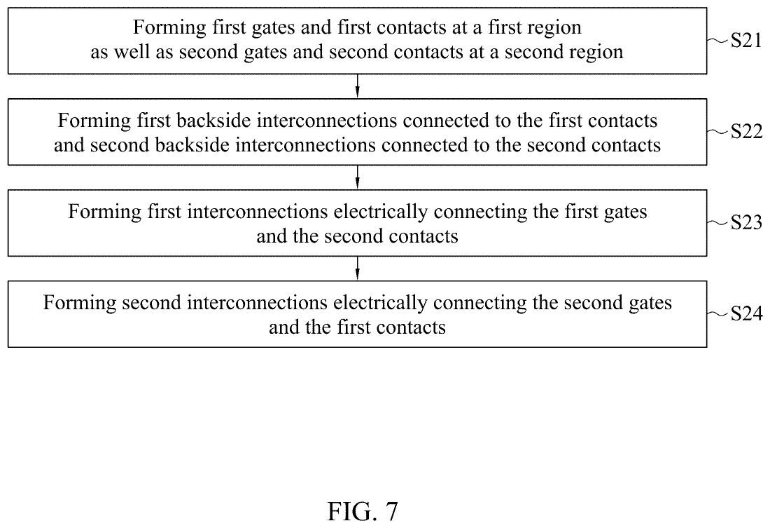

FIG. 7 is a flow chart illustrating a method 2 for manufacturing a semiconductor device according to various aspects of the present disclosure.

The method 2 begins with operation gate structures 20b) and second contacts (e.g., the S/D contacts 30eration S21 in which first gates (e.g., the gate structures 20a) and first contacts (e.g., the S/D contacts 30a) are formed at a first region (e.g., the regions R1 and R2) as well as second gates (e.g., the gate structures 20b) are formed at a second region (e.g., the region R3).

The method 2 continues with operation S22 in which first backside interconnections (e.g., the backside interconnections 40a) are formed to connect to the first contacts and second backside interconnections (e.g., the backside interconnections 40b) are formed to connect to the second contacts.

The method 2 continues with operation S23 in which first interconnections (e.g., the frontside interconnections 52a and/or 54b) are formed to electrically connect the first gates and the second contacts.

The method 2 continues with operation S24 in which second interconnections (e.g., the backside interconnections 52b and/or 54a) are formed to electrically connect the second gates and the first contacts.

The method 2 is merely an example, and is not intended to limit the present disclosure beyond what is explicitly recited in the claims. Additional operations can be provided before, during, and after the method 2, and some operations described can be replaced, eliminated, or move around for additional embodiments of the method.

Some embodiments of the present disclosure provide a semiconductor device. The semiconductor device includes a first gate, a first contact, a first backside interconnection, and a conductive layer. The first gate extends along a first direction and is configured to receive a first voltage. The first contact extends along the first direction and is configured to receive a second voltage different from the first voltage. The first backside interconnection is electrically coupled to the first contact. The conductive layer is over and electrically coupled to the first gate and extends along a second direction different from the first direction. The first gate and the first contact collectively form a first capacitor.

Some embodiments of the present disclosure provide a semiconductor device. The semiconductor device includes a first gate, a first contact, a first backside interconnection, a second contact, and a second backside interconnection. The first gate extends along a first direction and is configured to receive a first voltage. The first contact extends along the first direction and is configured to receive a second voltage different from the first voltage. The first backside interconnection is electrically coupled to the first contact. The second contact is electrically coupled to the first gate. The second backside interconnection is electrically coupled to the second contact. The first gate and the first contact collectively form a capacitor.

Some embodiments of the present disclosure provide a method of manufacturing a semiconductor device. The method includes: forming a first gate extending along a first direction; forming a first contact extending along the first direction; forming a second contact extending along the first direction, wherein the second contact is electrically coupled to the first gate; forming a first backside interconnection under and electrically coupled to the first contact; forming a second backside interconnection under and electrically coupled to the second contact, wherein the first gate and the first contact collectively form a first capacitor.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first gate extending along a first direction and configured to receive a first voltage;
a first contact extending along the first direction and configured to receive a second voltage different from the first voltage;
a first backside interconnection electrically coupled to the first contact; and
a conductive layer over and electrically coupled to the first gate and extending along a second direction different from the first direction,
wherein the first gate and the first contact collectively form a first capacitor.

2. The semiconductor device of claim 1, further comprising:
a second contact extending along the first direction and electrically coupled to the first gate through the conductive layer.

3. The semiconductor device of claim 2, further comprising:
a second backside interconnection under and electrically coupled to the second contact.

4. The semiconductor device of claim 3, wherein the first backside interconnection is free from overlapping the second backside interconnection along a second direction different from the first direction.

5. The semiconductor device of claim 4, further comprising:
a first backside conductive layer under and electrically coupled to the first backside interconnection; and
a second backside conductive layer under and electrically coupled to the second backside interconnection.

6. The semiconductor device of claim 1, further comprising:
a second gate extending along the first direction and electrically coupled to the first contact; and
a second contact extending along the first direction and electrically coupled to the first gate through the conductive layer.

7. The semiconductor device of claim 6, wherein the first gate and the first contact are included in a first type transistor, and the second gate and the second contact are included in a second type transistor.

8. The semiconductor device of claim 7, wherein the first type transistor and the second type transistor are arranged along the second direction.

9. The semiconductor device of claim 7, wherein the first type transistor and the second type transistor are arranged along the first direction.

10. The semiconductor device of claim 1, further comprising:
a metal-insulator-metal (MIM) structure under and electrically coupled to the first backside interconnection.

11. A semiconductor device, comprising:
a first gate extending along a first direction and configured to receive a first voltage;
a first contact extending along a first direction configured to receive a second voltage different from the first voltage;
a first backside interconnection electrically coupled to the first contact; and
a second contact electrically coupled to the first gate; and
a second backside interconnection electrically coupled to the second contact,
wherein the first gate and the first contact collectively form a capacitor.

12. The semiconductor device of claim 11, further comprising:
a second gate abutting the second contact and electrically floating.

13. The semiconductor device of claim 11, further comprising:
a second gate electrically coupled to the first contact.

14. The semiconductor device of claim 13, wherein the first gate and the first contact are included in a first type transistor, and the second gate and the second contact are included in a second type transistor.

15. The semiconductor device of claim 11, further comprising:
a first backside metal zero (BM0) layer electrically coupled to the first backside interconnection; and
a second BM0 layer electrically coupled to the second backside interconnection, wherein the first BM0 layer is spaced apart from the second BM0 layer are arranged along the first direction.

16. The semiconductor device of claim 11, further comprising:
a plurality of first backside metal zero (BM0) layers extending along a second direction different from the first direction and configured to receive the first voltage;
a plurality of second BM0 layers extending along the second direction and configured to receive the second voltage;
a plurality of first backside metal one (BM1) layers extending along the first direction and configured to receive the first voltage; and
a plurality of second BM1 layers extending along the first direction and configured to receive the second voltage.

17. A method of manufacturing a semiconductor device, comprising:
forming a first gate extending along a first direction;
forming a first contact extending along the first direction;
forming a second contact extending along the first direction, wherein the second contact is electrically coupled to the first gate;
forming a first backside interconnection under and electrically coupled to the first contact;
forming a second backside interconnection under and electrically coupled to the second contact,
wherein the first gate and the first contact collectively form a first capacitor.

18. The method of claim 17, further comprising:
forming a conductive layer over the first gate and extending along a second direction different from the first direction, wherein the conductive layer electrically connect the second contact and the first gate.

19. The method of claim 17, further comprising:
forming a first backside conductive layer under the first backside interconnection; and
forming a second backside conductive layer under the second backside interconnection,
wherein the first backside conductive layer and the second backside conductive layer are arranged along the first direction.

20. The method of claim 17, further comprising:
forming a second gate electrically coupled to the first contact,
wherein the first gate and the first contact are included in a first type transistor, and the second gate and the second contact are included in a second type transistor.
